(19) United States
(12) Patent Application Publication
(10) Pub. No.: US 2026/0142653 A1
(43) Pub. Date: May 21, 2026

(54) PULSE WIDTH MODULATION CIRCUIT FOR OUT OF AUDIO SIGNAL

(71) Applicant: SG MICRO CORP, Beijing (CN)

(72) Inventors: Xinmin YI, Beijing (CN); Liwei JIA, Beijing (CN); Haifeng XU, Beijing (CN)

(73) Assignee: SG MICRO CORP, Beijing (CN)

(21) Appl. No.: 18/994,716

(22) PCT Filed: Mar. 9, 2023
(86) PCT No.: PCT/CN2023/080487

§ 371 Date: Oct. 14, 2025

(30) Foreign Application Priority Data
Jul. 15, 2022 (CN) 202210831238.3

(51) Int. Cl. H03K 7/08

(52) U.S. Cl. CPC H03K 7/08

(57) ABSTRACT

A pulse width modulation circuit for an audio avoidance signal, which includes the circuit includes a power supply unit, a selection unit and a pulse width modulation unit; wherein the power supply unit includes a first voltage regulator and a second voltage regulator, which are respectively used to stabilize the system voltage and the bus voltage and output them alternately to the chip detection pin; the selection unit is used to divide the system voltage and the bus voltage, and output the selection voltage after comparing with the reference voltage, and the selection voltage controls the power supply unit and the pulse width modulation unit respectively; the pulse width modulation unit is used to receive the selection voltage of the selection unit, and realize the adjustment of the pulse width of the output signal based on the comparison of the enable signal. The method of the present application is simple and effective, and can further provide pulse width adjustment on the basis of PWM, so that the circuit has higher working efficiency and is more energy-saving and environmentally friendly under light load working conditions.

### RELATED APPLICATIONS

The present patent application document claims the benefit of priority to CN patent application No. 202210831238.3, filed Jul. 15, 2022, and entitled “pulse width modulation circuits for audio avoidance signals” the entire contents of which are incorporated herein by reference.

### BACKGROUND

### 1. Technical Field Text

The present application relates to the field of integrated circuits, and more particularly to pulse width modulation circuits of audio avoidance signals.

### 2. Background Information

With the continuous development of electronic technology, the demand for semiconductor chips in various industries continues to expand. Power management chips (Power Management Integrated Circuits) are chips that are responsible for the conversion, distribution, detection and other power management of electric power in electronic equipment systems. They are mainly responsible for identifying the CPU power supply amplitude, generating corresponding short-term waves, and driving the subsequent circuits to output power. As power management chips are increasingly widely used, the market's performance requirements for products are also getting higher and higher.

PWM (Pulse Width Modulation)/PFM (Pulse Frequency Modulation) is the most common control mode of power management chips. For example, in a general DC-DC converter, when the load current is large, the converter works in pulse width modulation mode, and when the load current is small, the converter works in pulse frequency modulation mode. In PFM mode, the frequency of the pulse decreases as the load current decreases. In addition, when the chip works in light load mode, in order to save chip power consumption and improve power utilization efficiency, the circuit often uses frequency modulation to realize power supply at the load end. When the frequency is low, the low-frequency vibration of the power stage inductor will bring noise that can be recognized by the human ear, which limits the scope of application of this circuit and has poor application performance.

In order to solve this problem, the existing technologies usually adopt the audio avoidance (OoA, Out of Audio) method to control the operating frequency of the circuits outside the audio range of 20 Hz to 20 KHz that can be recognized by the human ear. However, the usual practice in the existing technologies is to keep the chip's operating frequency greater than 20 kHz when it is lightly loaded. This higher frequency switching speed obviously reduces the chip's working efficiency under light load conditions. Therefore, in order to improve working efficiency, it is necessary to reduce the pulse width of the pulse signals as much as possible.

However, there is no power management chip in the existing technologies that can not only adjust the pulse width based on the change of the feedback voltage under normal load conditions, but also provide the adjustment of the pulse width in the output signal under different load conditions.

In view of the above problems, pulse width modulation circuits for audio avoidance signals are urgently needed.

### BRIEF SUMMARY

In order to solve the deficiencies in the existing technologies, the purpose of the present application is to provide pulse width modulation circuits for audio avoidance signals, wherein the bus voltage and the system voltage are selected by a selection unit, and different pulse width signals are output by a pulse width modulation unit, so that when the power supply control signal switches between light load and normal working states, different pulse width signals can be used as the basis for controlling the working state of the circuits.

### BRIEF DESCRIPTION OF THE DRAWINGS

FIG. 1 is a schematic diagram of a circuit structure of a pulse width modulation circuit for audio avoidance signals according to the present application.

### DETAILED DESCRIPTION OF THE DRAWINGS AND THE PRESENTLY PREFERRED EMBODIMENTS

The present application is further described below in conjunction with the accompanying drawings. The following embodiments are only used to more clearly illustrate the technical solution of the present application, and cannot be used to limit the protection scope of the present application.

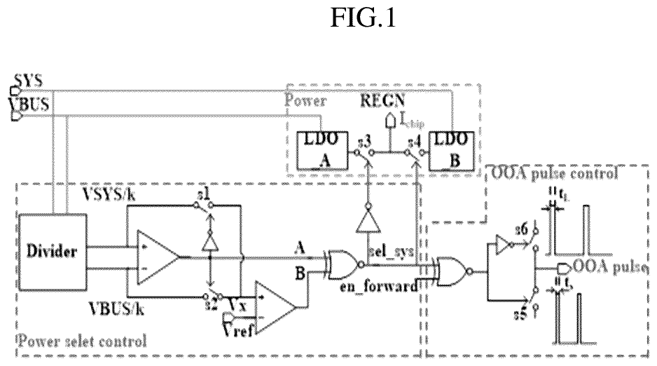

FIG. 1 is a schematic diagram of the circuit structure of a pulse width modulation circuit for audio avoidance signals of the present application. As shown in FIG. 1, a pulse width modulation circuit for an audio avoidance signals, wherein the circuit includes a power supply unit, a selection unit and a pulse width modulation unit; the power supply unit includes a first voltage regulator and a second voltage regulator, which are respectively used to stabilize the system voltage and the bus voltage and output them alternately to the chip detection pin; the selection unit is used to divide the system voltage and the bus voltage, and output the selection voltage after comparing them with the reference voltage, and the selection voltage controls the power supply unit and the pulse width modulation unit respectively; the pulse width modulation unit is used to receive the selection voltage of the selection unit, and adjust the pulse width of the output signal based on the comparison of the enable signal.

The power supply unit in the present application mainly provides appropriate power for the pulse width signal finally generated so that the pulse width signal is maintained at an appropriate level. The selection unit of the present application can make selections based on both the system voltage and the bus voltage to achieve the selection of the levels provided by different power supply units. In addition, the selection unit can also simultaneously achieve the adjustment selection of different widths of the pulse signal. The pulse width modulation unit in the present application can alternately generate two different pulse width signals at the same operating frequency, so that the circuit has different pulse widths under light load or non-light load conditions, thereby achieving control of the on-off state of the upper tube and the lower tube in the power control circuit.

Preferably, the alternating output of the power supply unit is realized based on the control of the selected voltage.

Similarly, the alternating output of the power supply unit and the alternating output of the pulse width control unit in the present application can be achieved based on the control of the selected voltage. In this way, the circuit can actually realize four different types of pulse modulation signals, two of which have the same level as the bus voltage and different pulse widths, and the other two have the same level as the system voltage and different pulse widths. Based on this method, the present application can ensure the working efficiency of the system in light load mode, and can gradually adjust the pulse width with the voltage in normal mode.

Preferably, the selection unit includes a frequency divider, a first comparator, a second comparator, a first NOT gate and a first XOR NAND gate; wherein the input ends of the frequency divider are respectively connected to the system voltage and the bus voltage, and the system voltage and the bus voltage divided by K times are output; the positive phase input end of the first comparator is connected to the system voltage divided by K times, the negative phase input end is connected to the bus voltage divided by K times, and the output end is connected to the first input end of the first XOR NAND gate; the positive phase input end of the second comparator is respectively connected to the system voltage and the bus voltage through the first switch S1 and the second switch S2, the negative phase input end is connected to the reference voltage, and the output end is connected to the second input end of the first XOR NAND gate; the output end of the first XOR NAND gate controls the third switch S3 in the power supply unit after passing through the NOT gate, and directly controls the fourth switch S4 in the power supply unit, and is input into the pulse width modulation unit.

In the present application, the frequency of the voltage after K-fold frequency division changes to K times of the original frequency, and the period of the voltage becomes one Kth of the original voltage period. The frequency divider in the present application can be a frequency divider commonly used in the existing technologies. After passing through the frequency divider, the two voltages are respectively input to the positive phase input terminal and the negative phase input terminal of the first comparator, so that the output of the comparator can realize the switching of high and low levels according to the size of the two voltages.

On the other hand, the two voltages in the present application can also be input to the non-inverting input terminal of the second comparator through two controlled switches, such as switch tubes, etc. In FIG. 1 of the present application, it is shown as a Vx signal, which can switch between the system voltage and the bus voltage according to the states of the first switch and the second switch.

It should be noted that the bus voltage and system voltage in the present application are the voltages on the BUS pin and SYS pin of the chip. According to the characteristics of the chip, in one embodiment of the present application, when the BUS pin receives the input signal of the chip, the SYS pin can be used as the output of the chip. In another operation mode, when the SYS pin receives an external input signal, the BUS pin can be used as the output of the chip. In the present application, the en_forward signal in FIG. 1 is an enable signal, which can characterize the working state of the chip of the present application. When the signal is at a high level, it indicates that the BUS pin is an input terminal, and when the signal is at a low level, it indicates that the SYS pin is an input terminal.

In the present application, the outputs of the first and second comparators pass through an XOR gate and become control signals of the other two units, thereby realizing control over the other two units.

Preferably, the switching states of the first switch S1 and the second switch S2 are opposite to each other; the switching states of the third switch S3 and the fourth switch S4 are opposite to each other.

In the present application, in order to make the output pulse width signal have different states, the first and second signals will not be turned on or off at the same time, and the same is true for the third and fourth switches.

Preferably, the first voltage regulator and the second voltage regulator in the power supply unit are both low voltage drop linear regulators.

In the present application, a low voltage difference linear regulator is used as a control and output unit for the system voltage and the bus voltage, so that the external circuit will not affect the magnitude of the two voltages, and can control the two voltages to maintain a relatively stable output when they fluctuate.

Preferably, the input end of the first regulator is connected to the bus voltage, and the output end is output to the chip detection pin after passing through the third switch S3; the input end of the second regulator is connected to the system voltage, and the output end is output to the chip detection pin after passing through the fourth switch S4.

In the present application, the first voltage regulator is used as a bus voltage regulating unit, and the second voltage regulator realizes the regulation of the system voltage. In addition, the output ends of the two voltage regulators are respectively connected to the test pin REGN of the chip through the switch tube to realize the voltage output.

Preferably, the pulse width modulation unit includes a second XOR gate, a second NOT gate, a fifth switch S5, and a sixth switch S6; wherein the first input end of the second XOR gate is connected to the output end of the selection unit, the second input end is connected to the enable signal, and the output end controls the fifth switch to be turned on and connected to the narrow pulse modulation signal after passing through the second NOT gate, or directly controls the sixth switch to be turned on and connected to the wide pulse modulation signal.

The pulse width modulation unit in the present application can realize wide pulse width modulation and narrow pulse width modulation respectively under the switching of the fifth switch state and the sixth switch state.

Preferably, when the enable signal is in a high level state, the bus voltage is less than the system voltage, the second switch S2 is disconnected, the first switch S1 is turned on, and the non-inverting input terminal of the second comparator is the system voltage; when the system voltage is greater than the reference voltage, the third switch S3 is turned on, the sixth switch S6 is turned on, and the output signal is a narrow pulse modulation signal of the bus voltage; when the system voltage is less than the reference voltage, the fourth switch S4 is turned on, the fifth switch S5 is turned on, and the output signal is a wide pulse modulation signal of the system voltage.

Preferably, when the enable signal is in a low level state, the bus voltage is greater than the system voltage, the second switch S2 is turned on, the first switch S1 is turned off, and the non-inverting input terminal of the second comparator is the bus voltage; when the bus voltage is greater than the reference voltage, the fourth switch S4 is turned on, the sixth switch S6 is turned on, and the output signal is a narrow pulse modulation signal of the system voltage; when the system voltage is less than the reference voltage, the third switch S3 is turned on, the sixth switch S6 is turned on, and the output signal is a wide pulse modulation signal of the bus voltage.

Table 1 is a state table of various signals in the circuit of the present application. As shown in Table 1, when the bus voltage, the system voltage and the reference voltage have different magnitudes, the circuit is in different states, and therefore the pulse signals outputted by the circuit are also different.

TABLE 1
Status table of each signal in the circuit

| | The second | Power supply | Enable | |
|---|---|---|---|---|
| | comparator | level | signal | Pulse Width |
| SYS > BUS | Vx > Vref | BUS | 1 | Narrow pulse |
| | Vx < Vref | SYS | 1 | Wide pulse |
| SYS < BUS | Vx > Vref | SYS | 0 | Narrow pulse |
| | Vx < Vref | BUS | 0 | Wide pulse |

In one embodiment of the present application, the reference voltage is 6V.

Preferably, when the bus voltage or the system voltage is greater than the reference voltage, the circuit outputs a narrow pulse modulation signal; when the bus voltage and the system voltage are both less than the reference voltage, the circuit outputs a wide pulse signal.

Similarly, in the present application, when either the system voltage or the bus voltage exceeds 6V, the circuit will select the lower voltage as the output level, and when both the system voltage and the bus voltage are less than 6V, the circuit will select the higher voltage as the output level.

The beneficial effect of the present application is that, compared with the existing technologies, the pulse width modulation circuits of the audio avoidance signals in the present application can realize the selection of the bus voltage and the system voltage through the selection unit, and realize the output of different pulse width signals through the pulse width modulation unit, so that the power control signal can have different pulse width signals as the basis for controlling the working state of the circuit when switching between the light load and normal working states. The method of the present application is simple and effective, and can further provide pulse width adjustment on the basis of PWM, so that the circuit has higher working efficiency and is more energy-saving and environmentally friendly under the light load working state.

The applicant of the present application has made a detailed explanation and description of the implementation examples of the present application in conjunction with the drawings in the specification. However, those skilled in the art should understand that the above implementation examples are only preferred implementation schemes of the present application, and the detailed description is only to help readers better understand the spirit of the present application, and it is not a limitation on the protection scope of the present application. On the contrary, any improvements or modifications based on the inventive spirit of the present application should fall within the protection scope of the present application.

1. A pulse width modulation circuit for an audio avoidance signal, comprising:
the circuit includes a power supply unit, a selection unit and a pulse width modulation unit; wherein,
the power supply unit includes a first voltage regulator and a second voltage regulator, which are respectively used to stabilize the system voltage and the bus voltage and output them alternately to the chip detection pin;
the selection unit is used to divide the system voltage and the bus voltage, and output a selection voltage after comparing them with a reference voltage, and the selection voltage controls the power supply unit and the pulse width modulation unit respectively;
the pulse width modulation unit is used to receive the selection voltage of the selection unit, and adjust the pulse width of the output signal based on the comparison of the enable signal.

2. The pulse width modulation circuit of the audio avoidance signal in claim 1, further comprising:
the alternating output of the power supply unit is achieved based on the control of the selection voltage.

3. The pulse width modulation circuit of the audio avoidance signal in claim 2, further comprising:
the selection unit includes a frequency divider, a first comparator, a second comparator, a first NOT gate and a first XOR gate; wherein,
the input end of the frequency divider is respectively connected to the system voltage and the bus voltage, and outputs the system voltage and the bus voltage divided by K times;
the positive phase input end of the first comparator is connected to the system voltage divided by K times, the negative phase input end is connected to the bus voltage divided by K times, and the output end is connected to the first input end of the first XOR gate;
the positive phase input end of the second comparator is respectively connected to the system voltage and the bus voltage through the first switch S1 and the second switch S2, the negative phase input end is connected to the reference voltage, and the output end is connected to the second input end of the first XOR gate;
the output end of the first XOR gate controls the third switch S3 in the power supply unit after passing through the NOT gate, and directly controls the fourth switch S4 in the power supply unit, and inputs it into the pulse width modulation unit.

4. The pulse width modulation circuit of the audio avoidance signal in claim 3, further comprising:
the switching states of the first switch S1 and the second switch S2 are opposite to each other; the switching states of the third switch S3 and the fourth switch S4 are opposite to each other.

5. The pulse width modulation circuit of the audio avoidance signal in claim 4, further comprising:
the first voltage stabilizer and the second voltage stabilizer in the power supply unit are both low voltage drop linear regulators.

6. The pulse width modulation circuit of the audio avoidance signal in claim 5, further comprising:
the input end of the first voltage regulator is connected to the bus voltage, and the output end is output to the chip detection pin after passing through the third switch S3;
the input end of the second voltage regulator is connected to the system voltage, and the output end is output to the chip detection pin after passing through the fourth switch S4.

7. The pulse width modulation circuit of the audio avoidance signal in claim 6, further comprising:
the pulse width modulation unit includes a second XOR gate, a second NOT gate, a fifth switch S5, and a sixth switch S6;
Wherein, the first input end of the second XOR gate is connected to the output end of the selection unit, the second input end is connected to the enable signal, and the output end controls the fifth switch to be turned on and connected to the narrow pulse modulation signal after passing through the second NOT gate, or directly controls the sixth switch to be turned on and connected to the wide pulse modulation signal.

8. The pulse width modulation circuit of the audio avoidance signal in claim 7, further comprising:
when the enable signal is in a high level state, the bus voltage is less than the system voltage, the second switch S2 is disconnected, the first switch S1 is turned on, and the non-inverting input terminal of the second comparator is the system voltage;
when the system voltage is greater than the reference voltage, the third switch S3 is turned on, the sixth switch S6 is turned on, and the output signal is a narrow pulse modulation signal of the bus voltage;
when the system voltage is less than the reference voltage, the fourth switch S4 is turned on, the fifth switch S5 is turned on, and the output signal is a wide pulse modulation signal of the system voltage.

9. The pulse width modulation circuit of the audio avoidance signal in claim 7, further comprising:
when the enable signal is in a low level state, the bus voltage is greater than the system voltage, the second switch S2 is turned on, the first switch S1 is turned off, and the non-inverting input terminal of the second comparator is the bus voltage;
when the bus voltage is greater than the reference voltage, the fourth switch S4 is turned on, the sixth switch S6 is turned on, and the output signal is a narrow pulse modulation signal of the system voltage;
when the system voltage is less than the reference voltage, the third switch S3 is turned on, the sixth switch S6 is turned on, and the output signal is a wide pulse modulation signal of the bus voltage.

10. The pulse width modulation circuit of the audio avoidance signal in claim 8 or 9, further comprising:
when the bus voltage or the system voltage is greater than the reference voltage, the circuit outputs a narrow pulse modulation signal;
when both the bus voltage and the system voltage are less than the reference voltage, the circuit outputs a wide pulse signal.
